(19) United States
(12) Patent Application Publication
(10) Pub. No.: US 2003/0227047 A1
(43) Pub. Date: Dec. 11, 2003

(54) Split-gate flash memory structure and method of manufacture

(76) Inventors: Cheng-Yuan Hsu, Hsinchu City (TW); Chih-Wei Hung, Hsin-chu City (TW); Chih-Ming Chen, Hsinchu City (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, TW

(21) Appl. No.: 10/064,094

(22) Filed: Jun. 11, 2002

(51) Int. Cl. H01L 29/76; H01L 21/336

(52) U.S. Cl. 257/314; 257/315; 257/317; 438/201; 438/211

(57) ABSTRACT

A split-gate flash memory structure. The flash memory structure mainly includes a substrate, a control gate over the substrate and a floating gate between the substrate and the control gate. A first side of the floating gate and the control gate are aligned. A second side of the floating gate protrudes beyond the control gate and has a corner with a sharp profile. The structure further includes spacers on the sidewalls of the control gate and the floating gate, a source region in the substrate on the first side of the floating gate, a drain region in the substrate on the second side of the floating gate and a select gate in the substrate between the spacers and the drain region. The sharp corner on the floating gate generates a higher electric field that speeds the erasure of data from the flash memory.

### BACKGROUND OF INVENTION

1. Field of Invention

The present invention relates to a method of forming flash memory. More particularly, the present invention relates to a split-gate flash memory structure and its method of manufacture.

2. Description of Related Art

Flash memory is a type of memory that permits multiple read/write and erase operations. Since stored data is preserved even if power to the device is cut off, flash memory is widely used as a non-volatile memory device in personal computers and electronic equipment.

A typical flash memory unit has doped polysilicon layers to function as floating gate and control gate and a substrate. The floating gate and the control gate are separated from each other by a dielectric layer. Meanwhile, the floating gate and the substrate are separated from each other by a tunnel oxide layer. To write/erase data, a bias voltage is applied to the control gate and the source/drain region so that electrons are injected into the floating gate or the electrons are pulled out from the floating gate. To read data off the flash memory, an operating voltage is applied to the control gate so that the charge-up state of the floating gate will affect the on/off state of the underlying channel. The on/off status of the channel determines the read-out to be a logic level “1” or “0”.

To erase data from the flash memory, the substrate, the drain (source) terminal or the control gate is at a relatively high potential. Tunneling effect is utilized so that electrons penetrate through a tunnel oxide layer to the substrate or drain (source) terminal (that is, the substrate erase or drain (source) side erase) or pass through the dielectric layer into the control gate. However, in erasing data inside the flash memory, the quantity of electrons bled out of the floating gate during a flash memory erasing operation is difficult to control. Ultimately, too many electrons may bleed out from the floating gate leading to a state often referred to as over-erasure. Severe over-erasure may result in a conductive channel underneath the floating gate even without the application of an operating voltage and hence lead to erroneous read-out data. To reduce over-erase problem, a three-gate-layer high-density flash memory is developed.

FIG. 1 a schematic cross-sectional view of a conventional split-gate flash memory unit. As shown in FIG. 1, the flash memory unit is constructed over a P-type silicon substrate 100. The flash memory unit has a tunnel oxide layer 102, and a floating gate layer 104 and a control gate layer 106 both made from polysilicon material. The floating gate 104 is positioned under the control gate 106. After fabricating the floating gate layer 104 and the control gate layer 106, impurities are implanted into the substrate 100 to form a source region 108 and a drain region 110. Finally, a polysilicon layer is deposited over the substrate 100 to form a select gate 112.

In the aforementioned flash memory, relative potential at the substrate, the drain (source) region or the control gate is raised during an erase operation. Tunneling effect is used to accelerate the electrons so that the electrons pass out through the corner 114 of the floating gate 104 and penetrate the dielectric layer 102 to arrive at the select gate 112. However, the corner 114 section on each side of the floating gate layer 104 may not have a sufficiently sharp profile to produce a high electric field during data erasure. Hence, a longer period is often required to complete a data erase operation.

### SUMMARY OF INVENTION

Accordingly, one object of the present invention is to provide a split-gate flash memory manufacturing method capable of producing sharp corners in a floating gate layer so that time required to erase data from the memory is reduced.

To achieve these and other advantages and in accordance with the purpose of the invention, as embodied and broadly described herein, the invention provides a method of manufacturing a split-gate flash memory. A tunnel oxide layer, a first conductive layer, a gate dielectric layer, a second conductive layer and a cap layer are sequentially formed over a substrate. The cap layer and the second conductive layer are patterned to expose the gate dielectric layer. A first patterned photoresist layer is formed over the substrate. The patterned photoresist layer exposes areas for forming a source region. Using the first patterned photoresist layer, the patterned cap layer and the patterned second conductive layer as a mask, the gate dielectric layer and the first conductive layer are etched to expose the tunnel oxide layer. A source region is formed in the substrate. After removing the first patterned photoresist layer, a first spacer is formed on the sidewall of the patterned cap layer, the patterned second conductive layer and the first conductive layer. Thereafter, a second patterned photoresist layer is formed over the substrate. The second patterned photoresist layer exposes an area for forming a drain region. Using the second patterned photoresist layer, the patterned cap layer and the patterned second conductive layer each having sidewall spacers as a mask, the gate dielectric layer and the first conductive layer are etched to expose the tunnel oxide layer. After removing the second patterned photoresist layer, a thermal oxidation process is carried out to produce sharp corners in the first conductive layer protruding into the second conductive layer. A second spacer is formed on the sidewalls of the first spacers and the first conductive layer. A third conductive layer is formed on the sidewall of the second conductive layer having corners. A drain region is formed in the substrate. The first conductive layer serves as a control gate of the flash memory, the second conductive layer serves as a floating gate of the flash memory and the third conductive layer serves as the select gate of the flash memory.

In this invention, the area for forming a control gate is patterned out first. Thereafter, the floating gate layer is patterned using the cap layer and the control gate as a self-aligned mask. Hence, process window is improved and some production cost is saved. Furthermore, one side of the floating gate and the control gate are aligned while the other side of the floating gate protrudes beyond the control gate to form a corner. A thermal oxidation is conducted to sharpen the corners of the floating gate protruding from the control gate. Because the corners of the floating gate protruding beyond the control gate have a sharper corner, a higher electric field is produced in a data erase operation. Hence, time required to erase data from the flash memory is shortened. Furthermore, the voltage applied to the control gate for erasing data may be reduced.

This invention also provides a split-gate flash memory structure. The flash memory structure mainly includes a substrate, a control gate over the substrate and a floating gate between the substrate and the control gate. The floating gate has a first side and a second side. The first side of the floating gate and the control gate are aligned. The second side of the floating gate protrudes beyond the control gate. The floating gate has corners with a sharp profile. The structure further includes spacers on the sidewalls of the control gate and the floating gate, a source region in the substrate on the first side of the floating gate, a drain region in the substrate on the second side of the floating gate and a select gate in the substrate between the spacers and the drain region. Other elements inside the structure include a cap layer over the control gate, a gate dielectric layer between the control gate and the floating gate and a tunnel oxide layer between the floating gate and the substrate.

In this invention, one side of the floating gate and the control gate are aligned. The other side of the floating gate protrudes beyond the control gate and has a sharp corner. Because the protruding side of the floating gate has a sharp corner, higher electric field is produced in a data erase operation. Hence, a shorter time is required for erasing data from the flash memory and the voltage applied to the control gate for erasing is reduced.

It is to be understood that both the foregoing general description and the following detailed description are exemplary, and are intended to provide further explanation of the invention as claimed.

### BRIEF DESCRIPTION OF DRAWINGS

The accompanying drawings are included to provide a further understanding of the invention, and are incorporated in and constitute a part of this specification. The drawings illustrate embodiments of the invention and, together with the description, serve to explain the principles of the invention. In the drawings,

FIG. 1 is a schematic cross-sectional view of a conventional split-gate flash memory unit;

FIGS. 2A to 2F are schematic cross-sectional views showing the progression of steps for producing a split-gate flash memory according to one preferred embodiment of this invention; and

FIG. 3 is a schematic cross-sectional view of a split-gate flash memory fabricated according to this invention.

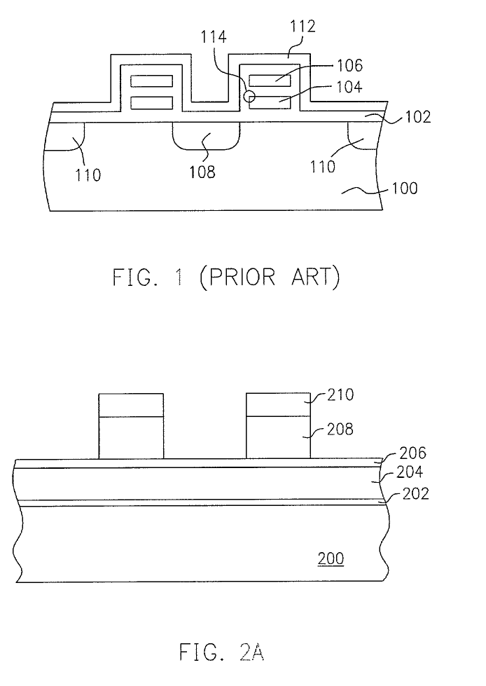

### DETAILED DESCRIPTION

Reference will now be made in detail to the present preferred embodiments of the invention, examples of which are illustrated in the accompanying drawings. Wherever possible, the same reference numbers are used in the drawings and the description to refer to the same or like parts.

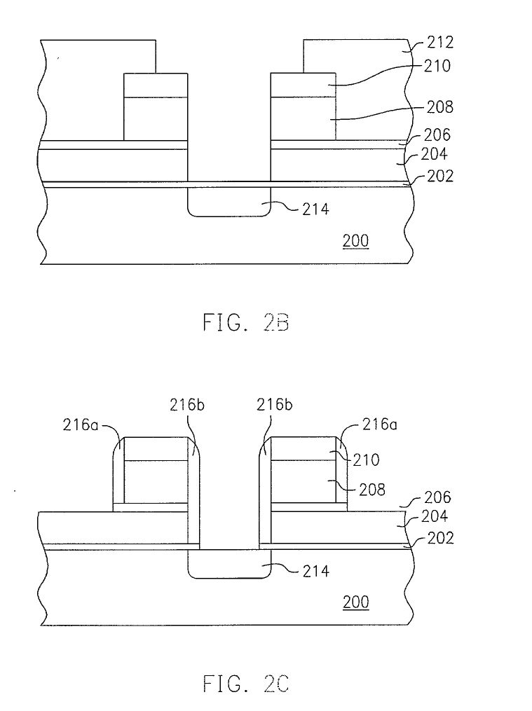

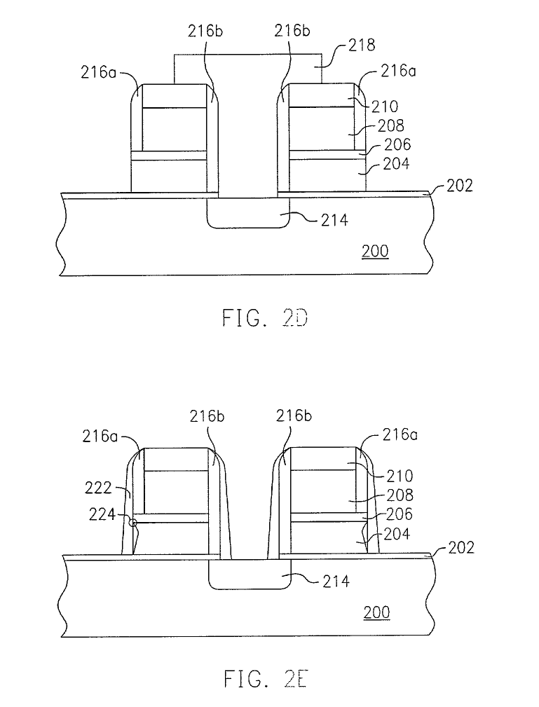

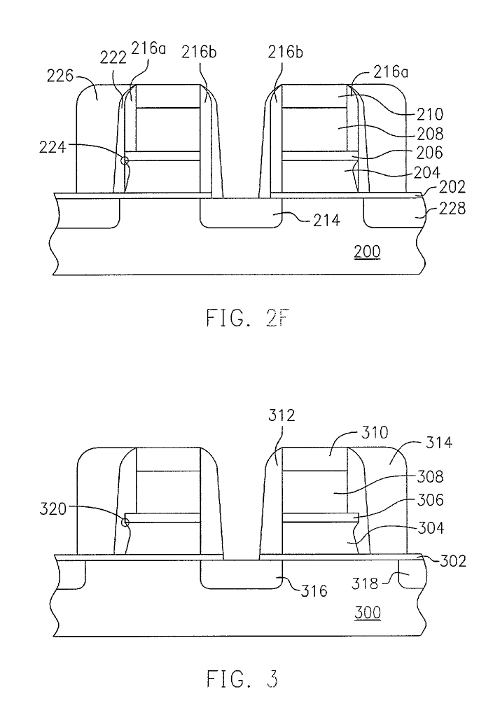

FIGS. 2A to 2F are schematic cross-sectional views showing the progression of steps for producing a split-gate flash memory according to one preferred embodiment of this invention. As shown in FIG. 2A, a tunnel oxide layer 202, a conductive layer 204 and a gate dielectric layer 206 are sequentially formed over a substrate 200. The tunnel oxide layer 202 having a thickness between about 90 Å to 100 Å is formed, for example, by thermal oxidation. The conductive layer 204 is a doped polysilicon layer formed, for example, by depositing undoped polysilicon in a chemical vapor deposition and then conducting an ion implant operation. After forming the conductive layer 204, any native oxide layer (not shown) on the surface of the conductive layer 204 is removed by etching using, for example, a hydrofluoric acid (HF) solution. The gate dielectric layer can be an oxide/silicide/oxide composite layer having a thickness ratio of 60 Å/70 Å/60 Å, for example. The dielectric layer 204 is formed by a low-pressure chemical vapor deposition, for example. Note that the gate dielectric layer can also be a silicon oxide layer, an oxide/silicide composite layer and so on.

A second conductive layer 208 is formed over the gate dielectric layer 206. The conductive layer 208 is a doped polysilicon layer formed, for example, by depositing undoped polysilicon in a chemical vapor deposition and then conducting an ion implant operation. Thereafter, a cap layer 210 is formed over the conductive layer 208. The cap layer 210, having a thickness between about 600 Å to 900 Å, is a silicon oxide layer formed, for example, by thermal oxidation. The cap layer 210 and the conductive layer 208 are patterned by conducting photolithographic and etching processes. The patterned conductive layer 208 serves as a control gate of the flash memory.

As shown in FIG. 2B, a patterned photoresist layer 212 is formed over the substrate 200. The patterned photoresist layer 212 exposes area for forming a drain region 214. Using the patterned photoresist layer 212, the cap layer 210 and the conductive layer 208 as an etching mask, the gate dielectric layer 206 and the conductive layer 204 are etched to expose the tunnel oxide layer 202. The conductive layer 204 is etched using the cap layer 210 and the conductive layer 208 as a self-aligned mask. Again, using the patterned photoresist layer 212, the cap layer 210 and the conductive layer 208 as a mask, ionic dopants are implanted into the substrate 200 to form the drain region 214.

As shown in FIG. 2C, the patterned photoresist layer 212 is removed. A spacer 216a is formed on the sidewalls of the conductive layer 208 and the cap layer 210. At the same time, a spacer 216b is also formed on the sidewalls of the conductive layer 204, the gate dielectric layer 206, the conductive layer 208 and the cap layer 210. The spacers 216a and 216b are formed, for example, by depositing insulating material over the substrate 200 to form an insulation layer (not shown). The insulation layer can be a silicon oxide layer formed, for example, by reacting reactive gases such as tetra-ethyl-ortho-silicate (TEOS)/ozone (O₃) in a chemical vapor deposition process. Finally, a portion of the insulation layer is removed in an anisotropic etching process. In the process of forming the spacers 216a and 216b, a portion of the gate dielectric layer 206 on the conductive layer 204 and a portion of the tunnel oxide layer 202 on the substrate 200 will also be removed.

As shown in FIG. 2D, another patterned photoresist layer 218 is formed over the substrate 200. The patterned photoresist layer 218 exposes an area for forming a drain region. Using the patterned photoresist layer 218 and the cap layer 210 and the conductive layer 208 with attached spacers 216a thereon as an etching mask, the gate dielectric layer 206 and the conductive layer 204 are etched. Ultimately, the tunnel oxide layer 202 is exposed to form a gate structure. The conductive layer 204 serves as a floating gate of the flash memory. Furthermore, the cap layer 210 and the conductive layer 208 with attached spacers 216a serve as a self-aligned mask when the conductive layer 204 is etched. Consequently, one side of the conductive layer 204 and the conductive layer 208 are aligned while the other side of the conductive layer 204 protrudes beyond the conductive layer 208.

As shown in FIG. 2E, the patterned photoresist layer 218 is removed. A thermal oxidation is conducted to sharpen the corners 224 on the conductive layer 204 that protrude beyond the conductive layer 208. Because the corners 224 attached to the conductive layer 204 (the floating gate) have a sharp profile, a higher electric field is produced at the corners 224 in a data erasing operation. Hence, data within a flash memory can be erased faster and voltage applied to the control gate can be lowered. Afterwards, a spacer 222 is formed on the sidewalls of the gate structure. The spacers 222 are formed, for example, by depositing insulating material over the substrate 200 to form an insulation layer (not shown). The insulation layer can be a silicon oxide layer formed, for example, by reacting reactive gases such as tetra-ethyl-ortho-silicate (TEOS)/ozone (O₃) in a chemical vapor deposition process. Finally, a portion of the insulation layer is removed in an anisotropic etching process.

As shown in FIG. 2F, a conductive layer 226 is formed over the substrate 200 between the gate structure and the area for forming a drain region. The conductive layer 226 can be a doped polysilicon layer formed, for example, by depositing undoped polysilicon in a chemical vapor deposition and then conducting an ion implant operation. The conductive layer 226 is formed on the sidewall of the side having sharp corner 224 on the conductive layer 204. The conductive layer 226 serves as a select gate for the flash memory. A drain region 228 is formed in the substrate 200 on the side with the conductive layer 226 (the select gate). Since subsequent operations for forming the flash memory are familiar to those skilled in the art of fabrication, detailed descriptions are omitted here.

In this invention, the conductive layer 204 is patterned out using the cap layer 210 and the control gate 208 as a self-aligned mask. Hence, the processing window is improved and some production cost is saved. Furthermore, one side of the conductive layer 204 and the conductive layer 208 are aligned while the other side of the conductive layer 204 protrudes beyond the conductive layer 208 to form sharp corners 224. A thermal oxidation is conducted to sharpen the corners 224 on the conductive layer 204. Because the corners 224 on the conductive layer 204 (the floating gate) are sharper, a higher electric field is produced in a data erase operation. Hence, time required to erase data from the flash memory is shortened and the voltage applied to the control gate for erasing data may be reduced.

FIG. 3 is a schematic cross-sectional view of a split-gate flash memory fabricated according to this invention. As shown in FIG. 3, the split-gate flash memory structure mainly includes a substrate 300, a tunnel oxide layer 302, a floating gate 304, a gate dielectric layer 306, a control gate 308, a cap layer 310, a spacer 312, a select gate 314, a source region 316 and a doped region 318.

The control gate 308 is formed over the substrate 300. The floating gate 304 is formed between the substrate 300 and the control gate 308. One side of the floating gate 304 and the control gate 308 are aligned. The other side of the floating gate 304 protrudes beyond the control gate 308. The floating gate 304 has sharp corners 320. The tunnel oxide layer 302 is formed between the substrate 300 and the floating gate 304. The gate dielectric layer 306 is formed between the control gate 308 and the floating gate 304. The cap layer 310 is formed over the control gate 308. The spacer 312 is formed on the sidewalls of the floating gate 304 and the control gate 308. The source region 316 is formed in the substrate 300 on one side of the floating gate 304. The drain region 318 is formed in the substrate 300 on the other side of the floating gate 304. The select gate 314 is formed over the substrate 300 between the spacer 312 on the side of the floating gate 304 having a sharp corner 320 and the drain region 318.

According to this invention, one side of the floating gate 304 and the control gate 308 are aligned together. The other side of the floating gate 304 protrudes beyond the control gate 308 and has a sharp corner 320. Because the corner 320 on the floating gate 304 is sharp, a higher electric field is produced that channels electrons rapidly through the sharp corner 320 into the select gate 314. Hence, a shorter time is required for erasing data from the flash memory and the voltage applied to the control gate 304 for erasing is reduced. In addition, a silicon nitride pad may also form over the spacers close to the substrate 300 so that electrons are prevented from leaking into the substrate through the sharp corner of the floating gate 304.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

1. A method of forming a split-gate flash memory, comprising the steps of:
providing a substrate;
sequentially forming a tunnel oxide layer, a first conductive layer, a gate dielectric layer, a second conductive layer and a cap layer over the substrate;
patterning the cap layer and the second conductive layer to expose the gate dielectric layer;
forming a first patterned photoresist layer over the substrate, wherein the first patterned photoresist layer exposes an area for forming a source region;
etching the gate dielectric layer and the first conductive layer to expose the tunnel oxide layer using the first patterned photoresist layer, the patterned cap layer and patterned second conductive layer as an etching mask;
forming the source region in the substrate using the first patterned photoresist layer, the patterned cap layer and the patterned second conductive layer as a mask;
removing the first patterned photoresist layer;
forming a first spacer on the sidewalls of the patterned cap layer, the patterned second conductive layer and the first conductive layer;
forming a second patterned photoresist layer over the substrate, wherein the second patterned photoresist layer exposes an area for forming a drain region;
etching the gate dielectric layer and the first conductive layer to expose the tunnel oxide layer using the second patterned photoresist layer, the patterned cap layer and the patterned second conductive layer both with the first spacer attached as an etching mask;
removing the second patterned photoresist layer;
conducting a thermal oxidation to sharpen the corner on the first conductive layer that protrudes beyond the second conductive layer;
forming a second spacer on the sidewalls of the first spacer and the first conductive layer;
forming a third conductive layer on the sidewall of the second conductive layer having a corner thereon; and
forming the drain region in the substrate.

2. The method of claim 1, wherein the first conductive layer serves as a floating gate of the flash memory.

3. The method of claim 1, wherein the second conductive layer serves as a control gate of the flash memory.

4. The method of claim 1, wherein the third conductive layer serves as a select gate of the flash memory.

5. The method of claim 1, wherein the gate dielectric layer includes an oxide/nitride/oxide composite layer.

6. The method of claim 1, wherein after the step of forming the first conductive layer but before forming the gate dielectric layer, further includes conducting an etching operation to remove any native oxide on the surface of the first conductive layer.

7. The method of claim 6, wherein the etchant for etching the native layer over the first conductive layer includes a diluted hydrofluoric acid solution.

8. The method of claim 1, wherein the first spacer is a silicon oxide layer formed by conducting a chemical vapor deposition using a tetra-ethyl-ortho-silicate (TEOS)/ozone (O₃) mixture as a gaseous reactant.

9. The method of claim 1, wherein the second spacer is a silicon oxide layer formed by conducting a chemical vapor deposition using a tetra-ethyl-ortho-silicate (TEOS)/ozone (O₃) mixture as a gaseous reactant.

10. The method of claim 1, wherein the first conductive layer, the second conductive layer and the third conductive layer are doped polysilicon layers.

11. A split-gate flash memory structure, comprising:
a control gate over a substrate;
a floating gate between the substrate and the control gate, wherein a first side of the floating gate and the control gate are aligned together, a second side of the floating gate protrudes beyond the control gate and the protruding side of the floating gate has a corner with a sharp profile;
a spacer on the sidewalls of the control gate and the floating gate;
a source region in the substrate on the first side of the floating gate;
a drain region in the substrate on the second side of the floating gate; and
a select gate over the substrate between the spacer and the drain region.

12. The split-gate flash memory of claim 11, wherein the structure includes a cap layer over the control gate.

13. The split-gate flash memory of claim 11, wherein the structure includes a gate dielectric layer between the control gate and the floating gate.

14. The split-gate flash memory of claim 11, wherein the gate dielectric layer includes an oxide/nitride/oxide composite layer.

15. The split-gate flash memory of claim 11, wherein the structure includes a tunnel oxide layer between the floating gate and the substrate.

16. The split-gate flash memory of claim 11, wherein material constituting the spacer includes silicon oxide.

17. The split-gate flash memory of claim 11, wherein material constituting the control gate, the floating gate and the select gate includes doped polysilicon.
